(19) United States
(12) Patent Application Publication
(10) Pub. No.: US 2007/0037399 A1
(43) Pub. Date: Feb. 15, 2007

(54) High-pressure device for closing a container in a clean room

(76) Inventors: Christoph Luetge, Unna (DE); Hans-Ottomar Kurtz, Dortmund (DE)

Correspondence Address: MARSHALL & MELHORN, FOUR SEAGATE, EIGHT FLOOR, TOLEDO, OH, 43604, US

(21) Appl. No.: 10/536,379

(22) PCT Filed: Nov. 13, 2003
(86) PCT No.: PCT/DE03/03756

§ 371 Date: Feb. 15, 2006

(30) Foreign Application Priority Data
Nov. 26, 2002 (DE) 102 55 231.2

(51) Int. Cl. B44C 1/22; H01L 21/306; C03C 25/68

(52) U.S. Cl. 438/745; 216/83; 156/345.11

(57) ABSTRACT

The invention relates to a very compact device and to a method for closing a container by means of a rotational symmetric lifting system, which contains a working piston and a guide cylinder and is operated essentially using the same fluid that is placed inside the container while serving a process medium. The front face of the working piston forms, at least in part, the closure part of the container or is joined to the closure part in a fixed manner. Ideally, a supercritical fluid is used both as a working medium for driving the piston and as the process medium.

High-pressure device for operating closures of vessels for clean-room applications

The invention relates to a very compact device and a process for operating closures of vessels by means of rotation-symmetric reciprocating piston mechanisms combined with a guide cylinder and mainly operated by a medium simultaneously used as process fluid in the pressure vessel. The upper face of the hydraulic piston at least forms a part of the vessel closure or it is provided with a rigid link to the said closure. The ideal medium used to drive the hydraulic piston and to operate the process is a supercritical fluid.

The spectre of products developed by the semiconductor manufacturing, opto-electronic and other industries is constantly expanding and the said products permit to realise the central functions with the aid or on the basis of micro or nano-structures. The said structures also react extremely sensitive to minor impurities during the production phase. Hence, ever more stringent requirements are specified for the admissible emission rates of components used in the said ambience. The cleaning steps required for nano-structured surfaces cannot be carried out by conventional cleaning agents or they are hardly feasible. For some time supercritical fluids have been used on a large scale as they enhance the wetting effects and cleaning results. These operations necessitate process pressures which range from 150 to more than 300 bar and which consequently require special equipment. So far high-pressure equipment with adequate mechanical properties was not directly suitable for clean-room operations or it was even unsuitable for such applications. This invention describes a high-pressure unit of a very compact design which is suited for clean-room applications and which only produces minor emissions when alternating load cycles take place at a high pressure level.

Reciprocating piston mechanisms rated for >150 bar are in a broad and diverse technical use and have been adequately described in patent and general technical literature. The hydraulic media are fluids and gases, water being preferably used for pressures up to approx. 160 bar and hydraulic oils for pressures in excess of 160 bar. Inert gases and air are common operating media. Hydraulic oil in fact provides important positive properties which, inter alia, ensure lubrication of the sliding surfaces, low compressibility and high duty temperature potential.

Detrimental effects which cannot be completely eliminated from pistontype systems include, inter alia, material erosion and hydraulic fluid leakage. Friction- and pressure-induced erosion, such as abrasion, evaporation and liquefaction, for example, occur to a limited extent even on the parent material itself and, in particular, in and on the sealing members. Material erosion in reciprocating piston units is a function essentially of the quality of the sliding surfaces and the machining tolerances of the components, of the sealing material and the radial contact pressure of the sealing member, and also of temperature.

Any leakage of the hydraulic fluid, certain quantities of which are entrained at every reciprocating stroke, is a function of, inter alia, quality of surface, viscosity, hydrostatic pressure in the cylinder chamber and also on the sealing design and the radial contact pressure.

High operating pressures necessitate adequate lubrication of the surfaces facing each other and running against each other, resulting in corresponding leakage quantities. This effect can be minimised by means of suitable sealing systems and high-quality surface treatment. The margins of increasing the contact pressure for retaining the leaks, however, are restricted by the fact that the degradation and erosion of the sealing material increases as pressure rises, with the consequences of emissions and short-term greater leakage quantities. In addition, the limits of load-bearing capacity and economic operational mode are also reached.

Impurities resulting from material abrasion and leakage from the afore-mentioned sources are of a very detrimental nature in the production zone, particularly in the case of clean-room processes. The clean-room classes are defined, for instance, in DIN 2083 or in Federal Standard 209D. Emissions of any type whatsoever have a direct influence on the quality of the products of these processes and a considerable scope of equipment and organisational input is applied to minimise such emissions, inevitably with high costs to be incurred. Oil-bearing contamination resulting from oil mists is of a very serious and detrimental nature, as oil-laden immissions are often chemically active and can be removed only by means of solvent-containing substances which must not be present in clean-room facilities and can, indeed, be extremely disadvantageous there.

For more sophisticated production chains, which use clean-room components that are not fully adequate, the sections are partitioned. The so-called “Maintenance Sections” accommodate the equipment unsuitable for clean-room operations and the so-called “White Rooms” accommodate the items of equipment suited for clean-room applications. The said configurations necessitate expensive lock-type transfer systems and organisational precautions to retain any impurity that might emanate from the “Maintenance is Section”.

It is known that oil-hydraulic reciprocating piston systems used in clean-room applications are somewhat problematic and must be rendered suitable for such facilities by means of appropriate exhausting systems [SWISS Contamination Control 5 (1992) No. 5, pages 8 ff]. Oil incrustations occurred on the semi-finished product when a pressing die was used for the production of CD blanks, for example. Investigations revealed that the hydraulic fluid was the source of impurities. The suitability required for clean-room facilities was restored by fitting sealed sleeves to the die connecting rods, by providing an exhaust connection for the press housing and by removing the air from the sleeves.

A further technical article discloses a pneumatic cylinder without a piston rod [Dr.-Ing. E. Fritz; Paper for the 1. Int. Forum Fluidtechnisches Kolloquium, Volume 2, pages 283 ff]. The suitability for clean-room duty was achieved by generating a partial vacuum in the space between the covering strip and the sealing strip. Vacuum connections were fitted to the cylinder tube for this purpose and the emissions were discharged and routed away.

A disadvantage of the above-mentioned reciprocating piston mechanisms with incorporated exhaust system is the fact that additional equipment is necessary to ensure minimum particle concentrations and provide continuous operation.

U.S. Pat. No. 5,314,574 describes a device for treatment that is used in wafer production facilities. The said document outlines a piston system which provides for the separation of the necessary rods and cylinders from the process chamber in such a manner that flexible bellows are placed between the protruding piston end plate and the bottom plate of the process vessel so that the piston rods and the cylinders are enclosed by the metal bellows that spread each time when the piston performs a stroke, thus ensuring suitability in clean-room facilities. A comparable assembly is outlined in the said patent. The disadvantage of such systems, however, is a substantial air displacement on the external side of the bellows because the folded surfaces have a relatively IS large surface area that is mainly located crosswise in relation to the motion of the rods and accelerated whenever a stroke is performed. Further disadvantages are involved in view of the sophisticated design and the susceptibility to failure on account of the wear caused on the bellow material.

U.S. Pat. No. 5,169,408 describes a rotation-symmetric vessel for wafer treatment which, inter alia, comprises a pneumatic reciprocating piston system and a process vessel that is fed with the wafer chips and used for the process itself. The reciprocating piston system consists of several pneumatic pistons, one pneumatic piston being arranged in the centre of the upper part of the process vessel and serving to lift and lower this vessel part. The lower process vessel part is linked to several rotation-symmetric pistons arranged outside the axis of rotation and used to lift and lower the lower vessel part. The agents mainly used in this vessel as described in the said patent are nitrogen and water. The disadvantage of this invention is the sophisticated reciprocating piston system which provides several pistons for one lifting operation and which requires that said pistons are synchronised. In this case, high pressures especially necessitate an absolutely synchronised motion of all reciprocating pistons, which require a sophisticated control unit. The pneumatic reciprocating pistons that are described in the said patent consequently restrict the use of the said device and process to low pressure levels.

U.S. Pat. No. 6,067,728 describes a device and process for drying of wafers using supercritical CO₂, a pneumatic-mechanical closure system being incorporated. The closure of the vessel cover is accomplished by means of a pneumatic piston and lever mechanism which permits a pre-pressurisation of this unit. The vessel cover is locked by means of clips. After closing the process chamber by the pneumatic-mechanical system, one or more static clips are positioned symmetrically on the edge of the said cover. Said clips are pushed mechanically over the edge of the vessel cover and base and ensure the tightness of the vessel during the process, when the internal pressure rises.

A disadvantage of the above-mentioned invention are the many movable parts, which may be regarded as critical in terms of emission, and which severely limit the number of reciprocating strokes and/or number of process cycles per unit of time. In addition, the many operations required also necessitate a sophisticated control unit.

The aim of this invention is to avoid additional exhaust and protective systems and/or a specific partition of the available space and/or the utilisation of several or different process and operating fluids by providing adequate technological and process-oriented solutions on the reciprocating piston unit. More-over, the aim encompasses forms of construction that satisfy the requirements for a safe clean-room operation and that permit small motions and an absolute minimum of movable parts.

The invention provides for a solution that complies with the main claim and that is related to a high-pressure device for operating closures of vessels suited for clean-room applications, said device mainly consisting of a base part and a closure with a sealing member arranged between said parts, the related process being implemented with at least one process fluid and by means of a rotation-symmetric reciprocating piston system, said system comprising at least one rotation-symmetric hydraulic piston with one guide cylinder each, the hydraulic piston being linked to the guide cylinder at the piston end that has at least one radial and circumferential reinforcement on its external surface so that the inner space between the guide cylinder and the hydraulic piston is separated into at least one lower cylinder chamber and one upper cylinder chamber so that at least one bore is provided in the guide cylinder for each of the chambers, said bores being connected to at least one valve that controls either directly or via tubing, the delivery to and the discharge from the cylinder chambers of the guide cylinder, characterised in that the fluid for driving the hydraulic piston is identical with the main component of the process fluid used in the pressure vessel, the upper face of the hydraulic piston either constituting part of the closure or being provided with a rigid connection to said closure of the vessel and that the major part of this closure also moves along the axis of rotation, the vessel being arranged on the opposite side of the upper face of the hydraulic piston, and that the lower face of the hydraulic piston is larger than the contact surface between the base part and the closure part of the vessel.

In addition, at least one of the sliding surfaces which are located on the inner wall side of the cylinder and on the respective piston surfaces and where the cylinder and the piston surfaces come into contact as members facing each other and move parallel to the axis of rotation, has a 60% support ratio, said figure being the ratio of the portion of peaks in relation to the portion of valleys in the surface structure, and/or said sliding surface is hardened to prevent galling of the sliding surfaces.

It is recommended that austenitic materials be used, but the device described in the invention is not restricted to this group of materials.

Numerous processes that are used to provide high support ratios are described in detail in the technical literature. Typical processes suitable for this purpose are, for instance, honing, lapping or tumbling. The hardening of the surfaces pre-treated by such a method can be performed by plasma nitriding, kolsterising or hard chroming. These processes are state of the art and offered by various specialist companies.

With a view to optimising the control an embodiment of the device described in this invention provides for at least one restrictor step and/or at least one additional valve in the delivery and discharge lines and/or outlet lines. This configuration ensures that the contact pressure of the hydraulic piston at the upper face always exceeds the pressure in the process chamber during the various loading and depressurising cycles normally initiated by the valve.

The function of the disclosed device is such that the switching of the valve initiates the pressurisation of the space underneath the lower face of the hydraulic piston and the vessel via the delivery lines and the bores with the aid of fluid, hence
the hydraulic piston thus moves from the position “Vessel open” to the position “Vessel closed” so that the vessel closes, and
the valve is switched at the end of the process in the vessel in such a way that the fluid in the lower cylinder chamber and in the process chamber is depressurised, and
further valve switching ensures that the upper cylinder chamber in the guide cylinder is pressurised with fluid via the delivery line and the bore so that the hydraulic piston returns to its starting position “Vessel open”.

As stated above, an advantageous embodiment of the process is characterised in that the process chamber and the lower cylinder chamber are fed simultaneously with fluid, the feed stream to the vessel being restricted or delayed so that the contact pressure in the sealing area between base part and closure of the vessel always exceeds the pressure in the vessel.

Analogously to the afore-mentioned process optimisation, there is a feature which constitutes an enhancement of the process, i.e. a simultaneous depressurisation of the vessel and the lower cylinder chamber restricts or delays the fluid discharge stream from the lower cylinder chamber so that the contact pressure in the sealing area between the base part and the closure of the vessel always exceeds the pressure in the process chamber.

Direct coupling of the pressures in the process and cylinder chambers and the mode of controlling the fluid streams in the individual piston motions substantially facilitate the control and regulating configuration compared to systems that are known as state of the art and this also permits high numbers of piston strokes at very high pressures.

A process configuration that bears particular advantages is that a supercritical fluid is used as medium which, for example, is carbon dioxide (CO₂), compressed air, nitrogen or an inert gas or a mixture thereof. A low percentage of cleaning substance may be added to the fluid.

A further advantageous embodiment of the process provides for a fluid that is a highly volatile medium from the group constituted by ethanol, methanol, isopropanol and comparable substances or mixtures thereof, or as option a gas mainly consisting of CO₂, oxygen, nitrogen, a noble gas or mixtures thereof. A low percentage of cleaning substance may be added to the fluid.

The process and the device described in this invention are well suited to regularly provide an operating pressure of >160 bar at the upper face of the hydraulic piston and/or in the process chamber and to operate the device and the process at pressures exceeding 160 bar.

A further advantage can be obtained by utilising the device for a process that is related to an application, production or process applied in the semi-conductor industries and/or in the wafer production.

Further fields of application that are open to the device described in the invention are processes, applications or production processes in the optics, pharmaceuticals and/or medical products industries. In particular, the medical/medicinal products industries make use of many autoclave-based processes, packaging and pressing operations that can be simplified and enhanced with the aid of the device described in this invention.

With regard to known reciprocating piston systems, the device thus disclosed is suited for an advantageous application in any industrial branch that is subject to stringent requirements for cleanliness of the process and, simultaneously, it satisfies high throughput rates and high pressures. The device is of a very compact and robust type in view of the design described and the minimised motions to be performed so that there are also significant economic advantages vis-à-vis the current state of the art.

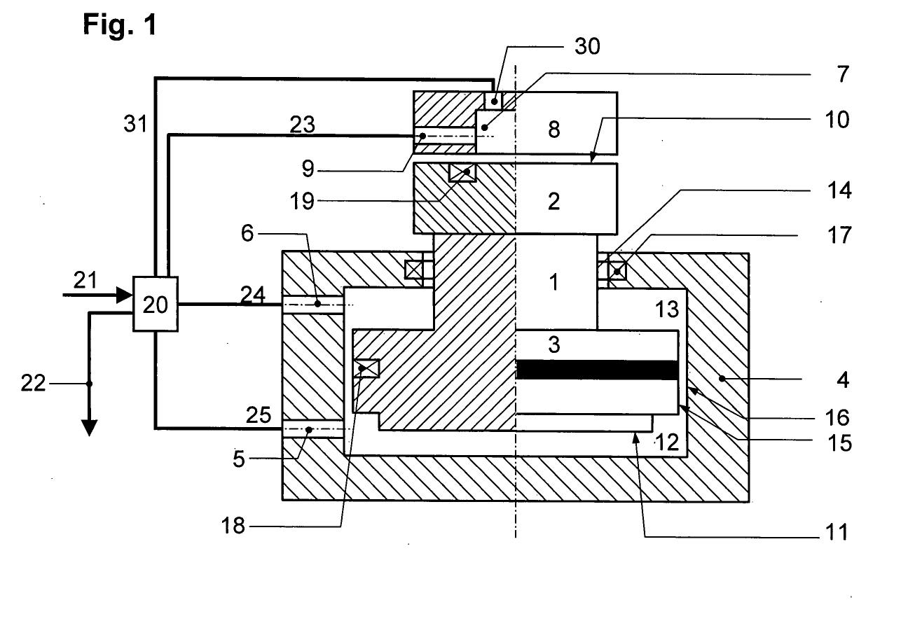

FIGS. 1 to 3 show a sectional view of the device.

FIG. 1: Reciprocating piston system with control unit

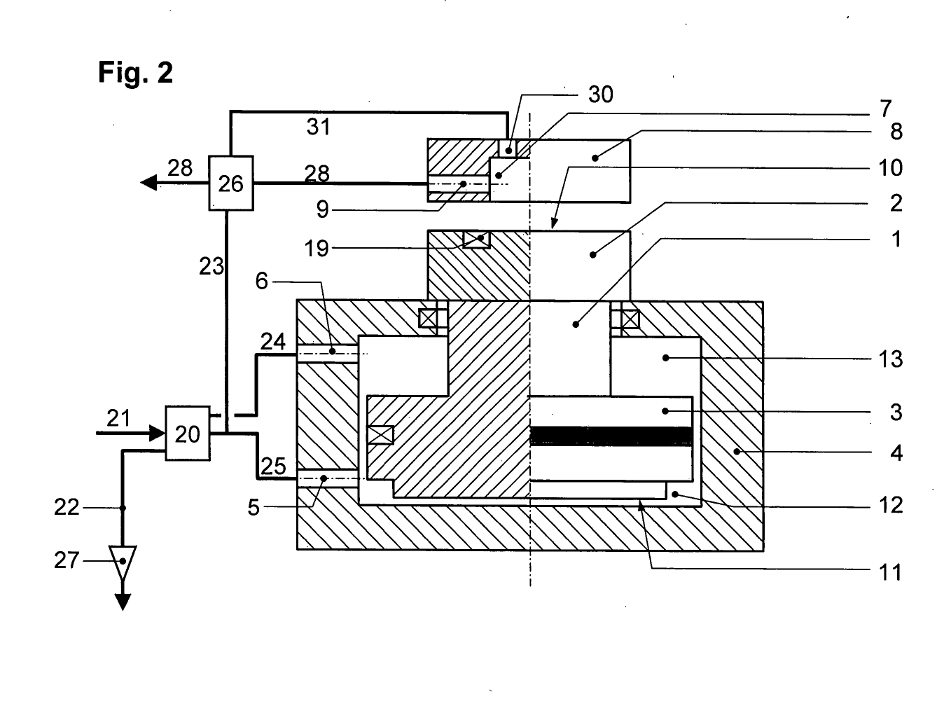

FIG. 2: Reciprocating piston system in starting position “Vessel opened”

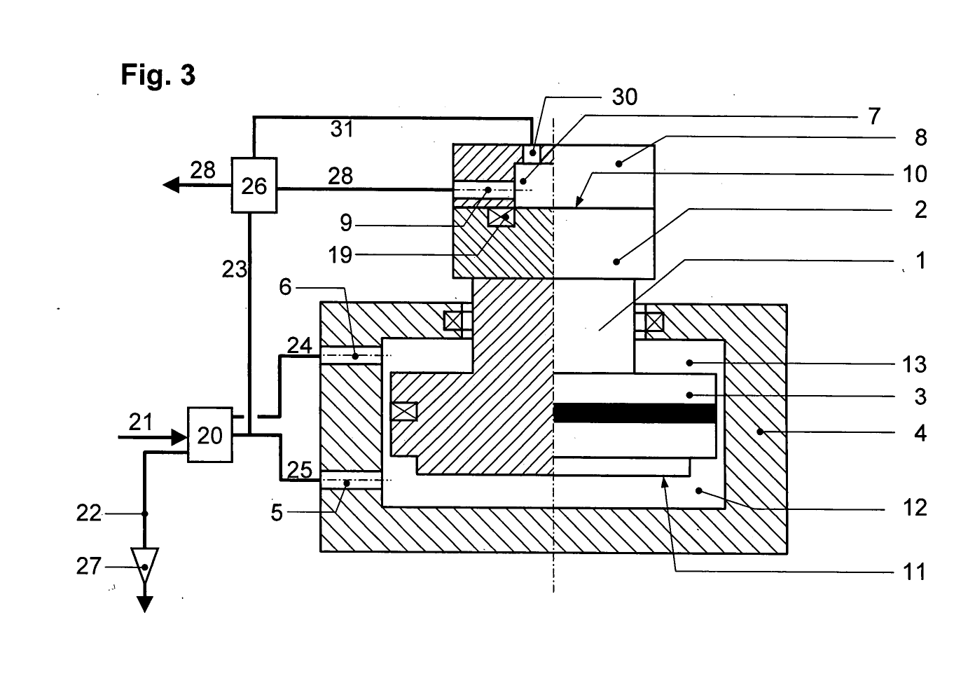

FIG. 3: Reciprocating piston system (“Vessel closed”)

The device and process are illustrated on the basis of this typical configuration, FIG. 1 showing a reciprocating piston system and the related control unit (20), incl. all delivery, feed and discharge lines connected to said unit (20).

FIG. 2 and FIG. 3 show a typical control unit in the form of valve (20), valve (26) and restrictor (27). Moreover, they illustrate the implementation of the process disclosed and the integration of the device described in the invention. The control cycle is configured in such a manner that valve (20) switching ensures that the space underneath lower face (11) of hydraulic piston (1) and vessel (8) are pressurised with fluid via the delivery lines and the bores, valve (26) performing the shut-off of delivery line (23) so that
hydraulic piston (1) moves from the starting position “Vessel open” (FIG. 2) to position “Valve closed (FIG. 3) so that the vessel closes, and
valve (20) is switched at the end of the cycle in such a manner that the fluid in lower cylinder chamber (12) and in process chamber (7) is depressurised, and
further valve switching ensures that upper cylinder chamber (13) in the guide cylinder is pressurised with fluid via delivery line (24) and bore (6) so that hydraulic piston (1) returns to its starting position “Vessel open”.

The example outlined below serves to illustrate the device and process in accordance with the invention.

FIG. 2 reflects that the device is a closure of a vessel which mainly consists of a static base part and a mobile closure. A sealing member is arranged between said components. The process chamber located between the two components is used to carry out processes with at least one process fluid. The closure is operated by means of a rotation-symmetric reciprocating piston system which comprises movable rotation-symmetric hydraulic piston (1) with guide cylinder (4).

The piston end located in guide cylinder (4) is provided with a radial, circumferential reinforcement (3) on the external surface so that the inner space between the guide cylinder and hydraulic piston is partitioned into two chambers. The guide cylinder has one bore for each of the two chambers, these bores being connected to the valve via delivery lines. Feed line (21) is used to supply the process and hydraulic fluid so that the same fluid is used for driving the piston and for processing in chamber (7). An additive can be added to the fluid, which is required for the process taking place in chamber (7).

The upper face of the hydraulic piston represents the closure of vessel (8) and is moved vertically along the axis of rotation. Lower face (11) of hydraulic piston (1) is larger than the contact surface between the base part and the closure part.

The device described above is illustrated in FIG. 2 and FIG. 3 and encompasses valve (20) as well as restrictor (27) arranged in discharge line (22) and valve (26) located in feed line (23).
At the start of reciprocating piston cycle, valve (26) is closed.
The respective setting of valve (20) initiates pressurisation of lower cylinder chamber (12) with fluid via delivery line (25) and bore (5), thereby permitting a simultaneous escape of fluid from upper cylinder chamber (13) via bore (6) and delivery line (24). During the initial phase lines (23 and 24) are closed by means of valves (20 and 26).
When a defined pressure is reached in delivery line (23) or at upper face (10) upon a set period of time, valve (26) opens and process chamber (7) is filled with fluid via bore (9) and line (29). The laden process fluid is discharged via bore (30) and line (31).
At the end of the process cycle in process chamber (7), the positioning of valve (28) will depressurise process chamber (7) as the fluid is discharged via bore (9) and delivery line (28).
During this depressurisation or shortly after this period, the positioning of valve (20) ensures that fluid is fed via delivery line (24) and bore (6) to upper cylinder chamber (13) and that simultaneously the depressurisation of lower cylinder chamber (12) takes place via line (25) and bore (5.) This makes the hydraulic piston return to its position “Vessel open” so that the process chamber can be loaded or unloaded.
Upon switching valve (28), which shuts down delivery line (23), the mechanism returns to the starting position of the whole cycle.

As stated above, the device suited for clean-room applications has the advantage that a simultaneous pressurisation of process chamber (7) and lower cylinder chamber (12) with fluid takes place and provides for a restriction of or a delay in the feed stream to vessel (8) via line (23) so that the contact pressure in the sealing face between the base part and closure part of the vessel always exceeds the pressure in the vessel.

A further embodiment analogous to the afore-mentioned optimisation also constitutes an advantage related to the simultaneous depressurisation of vessel (8) and lower cylinder chamber (12), which permits a restriction of or delay in the fluid discharge from lower cylinder chamber (12) so that the contact pressure in the sealing face between the base part and the closure part of vessel (8) always exceeds the pressure in process chamber (7).

Key to Flowsheet

1 Hydraulic piston
2 Ram of hydraulic piston
3 Extended section of piston bottom
4 Guide cylinder
5 Bore
6 Bore
7 Process chamber of pressure vessel
8 Pressure vessel
9 Bore
10 Upper face of hydraulic piston
11 Lower face of hydraulic piston
12 Lower cylinder chamber
13 Upper cylinder chamber
14 Sliding surface
15 Sliding surface
16 Sliding surface
17 Sealing member
18 Sealing member
19 Sealing member
20 Control unit/valve
21 Feed line
22 Discharge line
23 Delivery line
24 Delivery line to/from upper cylinder chamber
25 Delivery line to/from lower cylinder chamber
26 Valve/restrictor
27 Valve/restrictor
28 Delivery line
29 Pressure vessel
30 Bore
31 Pressure vessel

1-15. (canceled)

16. A high-pressure device for operating closures of vessel (8) and suited for clean-room applications, which comprises a base part and a closure part with a sealing member arranged between said parts, and for implementing the process with at least one process fluid and by means of a rotation-symmetric reciprocating piston system, said system comprising at least one rotation-symmetric hydraulic piston (1) with one guide cylinder (4) each, hydraulic piston (1) being linked to guide cylinder (4) at the piston end that has at least one radial and circumferential reinforcement (3) on its external surface so that the inner space between guide cylinder (4) and hydraulic piston (1) is separated into at least one lower cylinder chamber (12) and an upper cylinder chamber (13) and at least one bore (5 and 6) is provided in the guide cylinder (4) for each of cylinder chambers (12 and 13), said bores (5 and 6) being connected to at least one control unit (20) either direct or via lines (24 and 25), said settable unit controlling the delivery to and the discharge from cylinder chambers (12 and 13) of guide cylinder (4), wherein
the fluid for driving hydraulic piston (1) is identical with the main component of the process fluid used in pressure vessel (8) and the process fluid is either a supercritical gas or a highly volatile fluid,
the upper face of the hydraulic piston either constituting part of the closure or being provided with a rigid connection to said closure of the vessel and that the major part of this closure also moves along the axis of rotation referred to the hydraulic piston, the vessel being arranged on the opposite side of the upper face of the hydraulic piston and that the lower face of the hydraulic piston is larger than the contact surface between the base part and the closure part of the vessel and
at least one of sliding surfaces (14, 15 and 16), which are located on the inner wall side of the cylinder and on the respective piston surfaces and where the cylinder and the piston surfaces come into contact as members facing each other and moving parallel to the axis of rotation, has a 60% support ratio, said figure being the ratio of the portion of peaks in relation to the portion of valleys in the surface structure.

17. The device according to claim 16, wherein at least one of sliding surfaces (14,15 and 16), which are located on the inner wall side of the cylinder and on the respective piston surfaces and where the cylinder and the piston surfaces come into contact as members facing each other and move parallel to the axis of rotation, is subjected to a hardening process.

18. The device according to claim 16, wherein at least one of the lines connected to the bores is provided with a restrictor directly upstream or downstream of the valve.

19. The device according to claim 16, wherein the setting and control unit comprises at least one valve.

20. The device according to claim 16, wherein the setting and control unit comprises at least one static or dynamic fluid restrictor.

21. The device according to claim 16, wherein the feed stream to the vessel and the cylinder chamber is restricted and/or delayed when the vessel and the cylinder chamber are pressurized with fluid simultaneously.

22. The device according to claim 16, wherein a simultaneous depressurization of the vessel and the lower cylinder chamber takes place, the fluid discharge stream from the cylinder chamber underneath the lower face of the hydraulic piston being restricted and/or delayed.

23. The device according to claim 16, wherein the supercritical fluid is, for example, carbon dioxide (CO₂), compressed air, nitrogen or inert gas or a mixture thereof.

24. The device according to claim 16, wherein the highly volatile fluid is taken from the group constituted by ethanol, methanol, isopropanol and comparable substances or mixtures thereof, or as option a gas mainly consisting of CO₂, oxygen, nitrogen, a noble gas or mixtures thereof.

25. The device according to claim 16, wherein an operating pressure of >160 bar is regularly reached at the upper face of the hydraulic piston.

26. The process for the use of the device according to claim 16, comprising
as a result of the switching of the valve, the space underneath the lower face of the hydraulic piston and the vessel are filled with fluid, via the delivery lines and the bores,
the hydraulic piston thus moves from the starting position “Vessel open”, in which the vessel is open, to the position “Vessel closed”, in which the vessel is closed and closes the vessel, and
the valve is switched at the end of the process in the vessel in such a manner that the fluid in the space underneath the lower piston end and in the process chamber is depressurized,
further valve switching ensures that the upper cylinder chamber in the guide cylinder is pressurized with fluid via the delivery line and the bore so that the hydraulic piston returns to its starting position “Vessel open”.

27. The device according to claim 16, wherein the regular pressure in the vessel is >160 bar.
